(19) United States
(12) Patent Application Publication
(10) Pub. No.: US 2023/0418152 A1
(43) Pub. Date: Dec. 28, 2023

(54) INSERTS FOR SPACING IN RETICLE CONTAINERS

(71) Applicant: ENTEGRIS, INC., Billerica, MA (US)

(72) Inventors: Russ V. Raschke, Chanhassen, MN (US); Brian Wiseman, Glencoe, MN (US); Paul J. Magoon, Colorado Springs, CO (US); Huaping Wang, Eden Prairie, MN (US)

(21) Appl. No.: 18/211,968

(22) Filed: Jun. 20, 2023

Related U.S. Application Data
(60) Provisional application No. 63/356,277, filed on Jun. 28, 2022.

(51) Int. Cl. G03F 1/66; G03F 1/38; B65B 23/20

(52) U.S. Cl. CPC G03F 1/66; G03F 1/38; B65B 23/20

(57) ABSTRACT

Spacers include a base configured to be placed within depressions of one of a cover or a baseplate of a reticle pod, and a contact surface configured to contact the other of the cover and the baseplate. The spacers are configured to space the cover and the baseplate apart from one another such that sealing surfaces of the cover and the baseplate are separated by a gap. The depressions can be gripper pockets of the baseplate. Multiple spacers can be used in a reticle pod to provide the gap between sealing surfaces. The spacers can be installed to prepare a reticle pod for shipment.

### FIELD

This disclosure is directed to inserts for spacing parts of reticle containers apart from one another.

### BACKGROUND

Reticle containers can include hard contact surfaces. When reticle containers are shipped, they are typically shipped in their complete assembled state. During shipping, the contact surfaces may be subject to shock and/or vibration in excess of ordinary handling and operations for the reticle pod, leading to wear, damage, and particle generation that can affect the cleanliness or other performance of the reticle pod.

### SUMMARY

This disclosure is directed to inserts for spacing parts of reticle containers apart from one another.

By providing spacers located within the internal space of a reticle container, such as an inner pod of a reticle pod, a gap can be maintained between the contact surfaces while the reticle pod is shipped in the assembled state. The presence of such a gap can reduce or eliminate wear or damage resulting from shocks or vibration experienced during shipping of the reticle container. The gap can be sized such that the reticle container can still be completely assembled, for example having an inner pod be contained within the outer pod of the complete reticle container during such shipping. This allows reticle containers to be shipped with reduced risk of damage or particle generation, even when shipped as complete containers.

In an embodiment, an article includes a spacer for a reticle pod. The spacer includes a base of the spacer configured to engage with a depression formed in one of a cover or a baseplate of the reticle pod and a contact surface of the spacer configured to contact the other of the cover or the baseplate. The contact surface is configured to space the cover apart from the baseplate such that sealing surfaces included in the cover and the baseplate are spaced apart from one another by a gap.

In an embodiment, the gap has a width in a range from 20 μm to 1 mm.

In an embodiment, the spacer comprises a thermoplastic like for example polycarbonate (PC), polyether ether ketone (PEEK), perfluroalkoxy (PFA), and high-density polyethylene (HDPE).

In an embodiment, the depression is a gripper pocket formed in the first inner pod segment.

In an embodiment, the spacer further comprises a handling feature extending from the body.

In an embodiment a reticle pod includes an inner pod including a baseplate and a cover and one or more spacers. Each spacer includes a base configured to engage with a depression formed in one of the baseplate or the cover and a contact surface configured to contact the other of the baseplate or the cover. The contact surface is configured to space the baseplate apart from the cover such that baseplate sealing surfaces included in the baseplate and cover sealing surfaces included in the cover are spaced apart from one another by a gap.

In an embodiment, the gap has a width in a range from 20 μm to 1 mm.

In an embodiment, the reticle pod further includes an outer pod configured to accommodate the inner pod and the one or more spacers.

In an embodiment, the depression is a gripper pocket formed in the baseplate, and the contact surface is configured to contact the cover.

In an embodiment, the spacer further comprises a handling feature extending from the body.

In an embodiment, the one or more spacers includes a plurality of the spacers. In an embodiment, at least two of the plurality of the spacers are joined to one another by at least one handling feature.

In an embodiment, the spacers only contact the cover outside of the cover sealing surfaces and only contact the baseplate outside of the baseplate sealing surfaces.

A method of preparing a reticle pod for shipment includes placing one or more spacers into depressions formed in one of a cover or a baseplate of a reticle pod and assembling the cover and the baseplate to form an inner pod of the reticle pod. The spacers contact the cover and the baseplate. The cover and the baseplate are separated by a gap.

In an embodiment, the gap has a width in a range from 20 μm to 1 mm.

In an embodiment, the depression is a gripper pocket formed in the baseplate, and the contact surface is configured to contact the cover.

In an embodiment, the cover includes one or more cover sealing surfaces, the baseplate includes one or more baseplate sealing surfaces, and the spacers only contact the cover outside of the cover sealing surfaces and only contact the baseplate outside of the baseplate sealing surfaces.

In an embodiment, the method further includes placing the inner pod into an outer pod, the outer pod including a pod dome and a pod door and joining the pod dome to the pod door to enclose the inner pod of the reticle pod within the outer pod. In an embodiment, the method further includes shipping the reticle pod from a packing location to a destination location while the pod dome is joined to the pod door. In an embodiment, the method further includes removing the spacers from the reticle pod at the destination location.

### DRAWINGS

FIG. 1 shows a reticle container according to an embodiment.

FIG. 2 shows an inner pod of a reticle according to an embodiment.

FIG. 3 shows a perspective view of a spacer according to an embodiment.

FIG. 4 shows a spacer according to an embodiment.

### DETAILED DESCRIPTION

This disclosure is directed to inserts for spacing parts of reticle containers apart from one another.

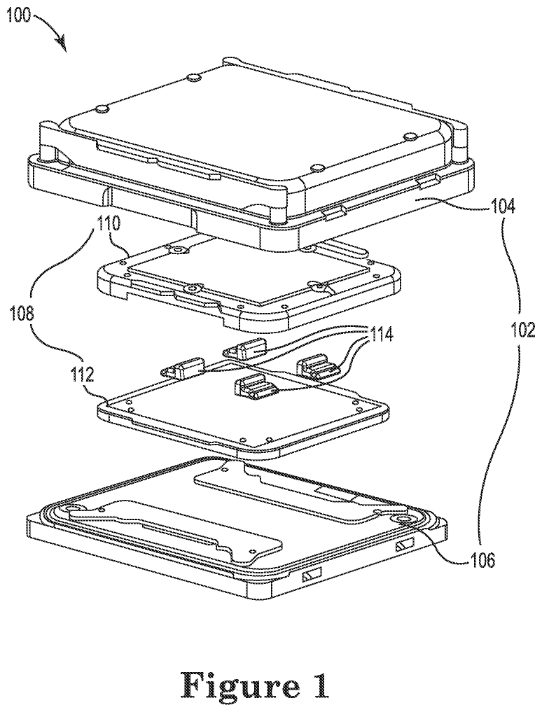

FIG. 1 shows a reticle container according to an embodiment. Reticle container 100 includes outer pod 102 including a pod dome 104 and a pod door 106. Reticle container 100 further includes inner pod 108 including a cover 110 and a baseplate 112. One or more spacers 114 can be placed within the inner pod 108.

Outer pod 102 forms an exterior of reticle container 100. Outer pod 102 is configured to accommodate inner pod 108. When reticle container 100 is shipped to a destination, the reticle container can be assembled with the inner pod 108 contained within the outer pod 102. The outer pod 102 can be composed of pod dome 104 and pod door 106.

Inner pod 108 is an inner pod of reticle container 100, configured to accommodate a reticle. The inner pod includes cover 110 and baseplate 112. Cover 110 and baseplate 112 can be configured to contact one another during typical use, for example at corresponding sealing surfaces provided on each of cover 110 and baseplate 112. Cover 110 and baseplate 112 can be made of metal materials, and further can have metal plating, for example at least at some of the sealing surfaces. The cover 110 and baseplate 112 can be spaced apart from one another at other times, for example during storage or shipment, for example using one or more of spacer 114.

Spacer 114 can be included in reticle container 100 to space cover 110 and baseplate 112 apart from one another when inner pod 108 is assembled. The spacer 114 can include one or more spacing contacts configured to engage with a depression formed in one of cover 110 or baseplate 112, and to contact the other of the cover 110 or baseplate 112 so as to space the cover 110 and baseplate 112 apart from one another. The depression can be any suitable recess or depression formed in cover 110 or baseplate 112. In an embodiment, the depression can be included specifically for accommodation of the spacer 114. In an embodiment, the depression can be an existing feature of the cover 110 or baseplate 112, for example a gripper pocket, a gripper exclusion zone, a pellicle recess, or any other such feature of cover 110 or baseplate 112. The fit between spacer 114 and the depression is such that the spacer 114 can be readily placed into or removed from the depression. In an embodiment, the spacer 114 does not attach to or become fixed to the depression. The spacer 114 can rest in the depression such that the spacer 114. The spacer 114 can be configured to be removable from the depression by manual or automated handling of the spacer 114. The spacer 114 can contact the cover 110 and the baseplate 112 such that the respective sealing surfaces remain separated by a gap. The gap is such that the cover 110 and the baseplate 112 do not contact one another when spacer 114 is installed into the inner pod 108. In an embodiment, the gap can be maintained when the cover 110 and the baseplate 112 are assembled with spacer 114 in place and placed into the outer pod 102. When inner pod 108 is placed in outer pod 102 and outer pod 102 is closed, the gap can have a size of between 20 micrometer (μm) and 1 millimeter (mm). In an embodiment, the spacer 114 can include one or more spring members configured to increase a size of the gap when inner pod 108 is not contained in outer pod 102, relative to the size of the gap maintained when inner pod 108 is contained within the outer pod 102.

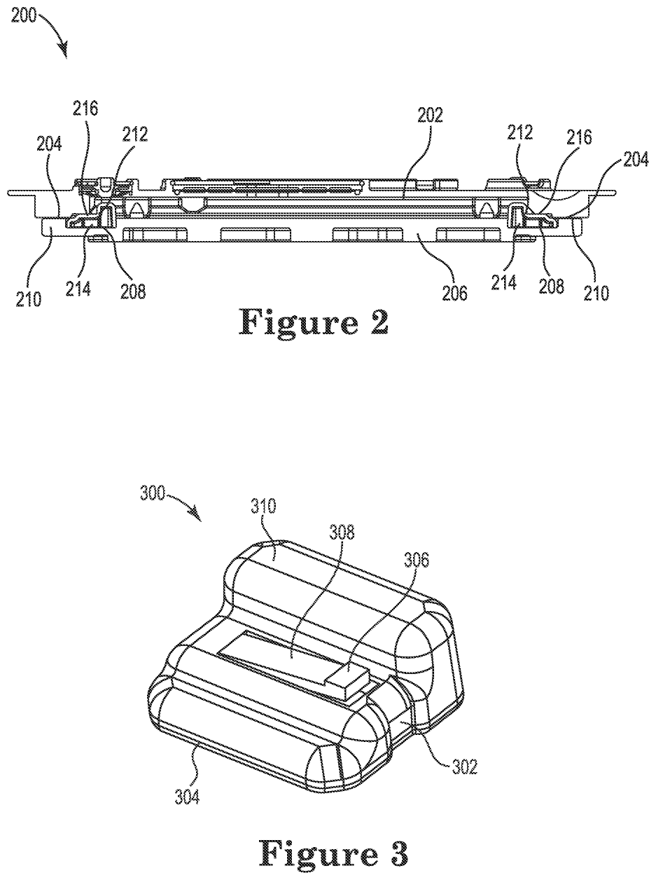

FIG. 2 shows an inner pod of a reticle according to an embodiment. Inner pod 200 includes cover 202 having cover sealing surface 204 and baseplate 206 having depression 208 and baseplate sealing surface 210. Spacer 212 includes a base 214 and a contact surface 216.

Cover 202 is a cover of inner pod 200. Cover 202 is configured to, when joined with baseplate 206, define an internal space capable of accommodating a reticle. Inner pod 200 can be used in a reticle pod such as reticle pod 100 shown in FIG. 1 and described above. In an embodiment, inner pod 200 can be contained within an outer pod such as outer pod 102 as shown in FIG. 1 and described above. Cover 202 includes cover sealing surface 204. Cover sealing surface 204 is a portion of cover 202 configured to contact corresponding locations of the baseplate sealing surface 210 during ordinary use of the inner pod 200 to contain a reticle. Cover sealing surface 204 can be positioned to correspond to a baseplate contact surface 210.

Baseplate 206 is a baseplate of the reticle pod 200. Baseplate 206 is configured to, when joined with cover 202, define an internal space capable of accommodating a reticle. Baseplate 206 includes one or more depressions 208. The depressions 208 are recesses into the baseplate 206. The depressions 208 can have any suitable shape and depth. The depressions 208 can be features included according to reticle pod standards, such as gripper pockets configured to allow automation to access a bottom side of a reticle stored in inner pod 200. Baseplate sealing surface 210 is configured to contact the cover sealing surface 204 when the reticle pod 200 is in ordinary use, for example to contain a reticle. The baseplate sealing surface is configured to correspond to the cover sealing surface 204.

Spacer 212 can be included in inner pod 200 to space cover 202 apart from baseplate 206. The spacer 212 can be an article including a base 214 at one side and a contact surface 216 provided on a side opposite base 214. Base 214 is configured to be received in one of the depressions 208 included in baseplate 206. The base can be shaped and sized to fit securely within its corresponding depression 208, for example having very small to no play within the space. The contact surface 216 is on a side of the spacer 212 opposite the base 214. The distance from base 214 to contact surface 216 is such that when the base is installed into depression 208 and the contact surface 216 contacts the cover, a gap having a width is formed between the cover sealing surface 204 and the baseplate sealing surface 210. The gap can be maintained even when inner pod 200 is placed into an outer pod such as outer pod 102 and the outer pod is closed. The spacer 214 can be any suitable material selected based on potential for particle generation when used with the materials of cover 202 and baseplate 206. Non-limiting examples of suitable materials include polyolefins. In an embodiment, the spacer 214 can include or be made entirely of high-density polyethylene. In an embodiment, the spacer 214 can include or be made entirely of polycarbonate. In an embodiment, the spacer 214 can include or be made entirely of polyether ether ketone. In an embodiment, the spacer 214 can include or be made entirely of perfluoroalkoxy. In an embodiment, spacer 214 can be made of a compressible material, such that a gap having a first width that is maintained when cover 202 and baseplate 206 are pressed together by an outer pod containing inner pod 200, such as outer pod 102 as described above and shown in FIG. 1. In this embodiment, the spacer can provide a gap having a second width, greater than the first, when the inner pod 200 is not compressed, for example when cover 202 rests on the spacers 214 by the force of gravity and inner pod 200 is not pressed by contact with an outer pod.

Spacer 214 can be included in inner pod 200 when it is desired to space cover 202 apart from baseplate 206, for example when shipping or storing inner pod 200. In an embodiment, at least three spacers 214 are included in inner pod 200 when it is desired to space cover 202 apart from baseplate 206.

While FIG. 2 shows the depression 208 as being formed in the baseplate 206 and contact surface 216 contacting the cover 202, these can be reversed in embodiments, with depression 208 being formed instead in cover 202 and base 214 being inserted into this depression 208, with contact surface 216 contacting the baseplate 204.

FIG. 3 shows a perspective view of a spacer according to an embodiment. Spacer 300 includes a body 302 including base 304 on one side and a contact surface 306 on a side opposite the base 304. The body 302 is configured to be inserted into depressions in one of a cover or a baseplate of a reticle pod, and to contact the other of the cover or the baseplate such that the cover and the baseplate are separated from one another by a gap. The body 302 can include any suitable material, such as a polyolefin. Non-limiting examples of materials for body 302 include high-density polyethylene or polycarbonate. In an embodiment, the body 302 can include a resilient material capable of being compressed. The resilient material can be selected such that a first gap size is maintained when the spacer 300 separates the cover and the baseplate without any additional force being applied, and a second gap size when the cover and the baseplate are pressed together by an outer pod containing the cover and baseplate. The second gap can be smaller than the first gap. In an embodiment, instead of a resilient material, the contact surface 306 can be connected to body 302 by a member capable of deflection such as a spring arm 308 so as to provide the first and second gap sizes. The body 302 includes a base 304 configured to be received in depressions formed in one of the cover or the baseplate. For example, base 304 can be received in gripper pockets formed in a baseplate of the inner pod into which spacer 300 is installed. The body 302 also includes a contact surface 306 opposite the base 304. The contact surface is configured to contact the other of the cover or the baseplate, such that spacer 300 contacts both the cover and the baseplate of an inner pod that spacer 300 is installed in. The distance from base 304 to contact surface 306 is selected such that when base 304 contacts one of a cover or a baseplate and contact surface 306 contacts the other of the cover or the baseplate, the cover and baseplate are spaced apart by one another. The spacing apart of the cover and the baseplate by contact with spacer 300 is such that a gap exists between sealing surfaces of the cover and the baseplate. In an embodiment, the gap has a width in a range from 20 μm to 1 mm. The body 302 of spacer 300 can include a handling feature 310 configured to allow manipulation of the spacer 300. In the embodiment shown in FIG. 3, the handling feature 310 is a projection extending vertically above the contact surface 306. In embodiments, the handling feature can instead include horizontal projections, flanges, or the like. In embodiments, the handling feature 310 is configured to be engaged by a user, for example a handle for being grasped. In embodiments, the handling feature is configured to be manipulated by automation, for example providing flanges, tabs, grooves, recesses, openings, or the like configured to interface with an automated handling device such as a robotic arm.

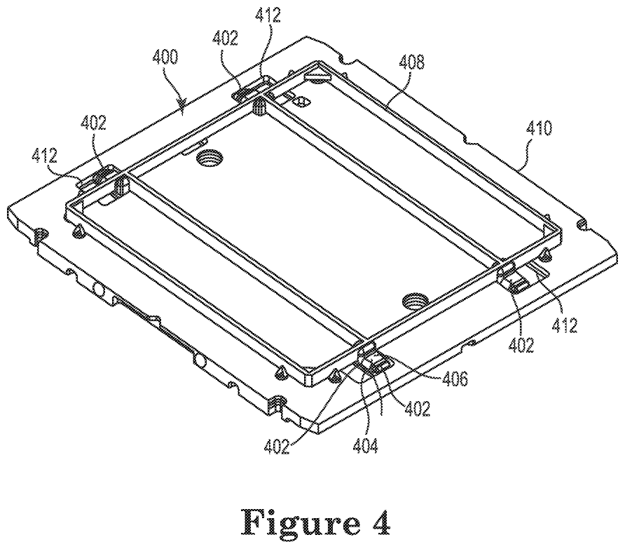

FIG. 4 shows a spacer according to an embodiment. Spacer 400 includes a plurality of spacer bodies 402 each including a base 404 and a contact surface 406. A handling feature 408 connects at least two of the plurality of spacer bodies.

Spacer 400 includes a plurality of spacer bodies 402. The spacer bodies 402 are bodies configured to be inserted into depressions in one of a cover or a baseplate of a reticle pod, and to contact the other of the cover or the baseplate such that the cover and the baseplate are separated from one another by a gap. The spacer bodies 402 can include any suitable material, such as a polyolefin. Non-limiting examples of materials for spacer bodies 402 include high-density polyethylene, perfluoroalkoxy, polyether ether ketone, or polycarbonate. In an embodiment, the spacer bodies 402 can include a resilient material capable of being compressed. The resilient material can be selected such that a first gap size is maintained when the spacer 400 separates the cover and the baseplate without any additional force being applied, and a second gap size when the cover and the baseplate are pressed together by an outer pod containing the cover and baseplate. The second gap can be smaller than the first gap. The spacer body 402 includes a base 404 configured to be received in depressions formed in one of the cover or the baseplate. For example, base 404 can be received in gripper pockets formed in a baseplate of the inner pod into which spacer 400 is installed. The spacer body 402 also includes a contact surface 406 opposite the base 404. The contact surface is configured to contact the other of the cover or the baseplate, such that spacer 400 contacts both the cover and the baseplate of an inner pod that spacer 400 is installed in. The distance from base 404 to contact surface 406 is selected such that when base 404 contacts one of a cover or a baseplate and contact surface 406 contacts the other of the cover or the baseplate, the cover and baseplate are spaced apart by one another. The spacing apart of the cover and the baseplate by contact with spacer 400 is such that a gap exists between sealing surfaces of the cover and the baseplate. In an embodiment, the gap has a width in a range from 20 μm to 1 mm.

Handling feature 408 can join two or more of the spacer bodies 402. Handling feature 408 can be configured to facilitate handling of the spacer 400, for example by providing a surface that can be gripped by a user or an automated tool such as a robotic arm to place or remove the spacer bodies 402 from the respective recesses where they are accommodated. In the embodiment shown in FIG. 4, the handling feature 408 is tab 410 projecting from the handling feature 408. Handling feature 408 can extend such that it is located entirely within the internal space of an inner pod into which spacer 400 is installed. The handling feature 408 can be configured to avoid contact with the cover and the baseplate of the inner pod when spacer 400 is installed. In an embodiment, at least a portion of the handling feature 408 can contact one of the cover or the baseplate of the inner pod when spacer 400 is installed. In an embodiment, the handling feature 408 can contact the cover or the baseplate of the inner pod such that a gap is formed between the cover and baseplate when the inner pod includes the spacer 400 and the inner pod is not contained in an outer pod. The gap provided by contact of handling feature 408 with the cover or the baseplate can be larger than a gap maintained by the spacer body 402 when the inner pod is contained within a larger pod. In an embodiment, the bases 404 can be sized so as to be smaller than the recesses 412 of the baseplate 410, such that there is space in the recesses 412 allowing users or automated tools to reach under the handling feature 408 to lift the spacer 400 out of the baseplate 410.

Aspects:

It is understood that any of aspects 1-5 can be combined with any of aspects 6-13 or any of aspects 14-20. It is understood that any of aspects 6-13 can be combined with any of aspects 14-20.

Aspect 1. An article comprising:
a spacer for a reticle pod, the spacer including:
   a base of the spacer configured to engage with a depression formed in one of a cover or a baseplate of the reticle pod; and
   a contact surface of the spacer configured to contact the other of the cover or the baseplate, wherein:
   the contact surface is configured to space the cover apart from the baseplate such that sealing surfaces included in the cover and the baseplate are spaced apart from one another by a gap.

Aspect 2. The article according to aspect 1, wherein the gap has a width in a range from 20 μm to 1 mm.

Aspect 3. The article according to any of aspects 1-2, wherein the spacer comprises a thermoplastic such aspolycarbonate, polyether ether ketone, perfluoroalkoxy and high-density polyethylene.

Aspect 4. The article according to any of aspects 1-3, wherein the depression is a gripper pocket formed in the first inner pod segment.

Aspect 5. The article of claim 1, wherein the spacer further comprises a handling feature extending from the body.

Aspect 6. A reticle pod, comprising:
an inner pod including a baseplate and a cover; and
one or more spacers, each spacer including:
   a base configured to engage with a depression formed in one of the baseplate or the cover; and
   a contact surface configured to contact the other of the baseplate or the cover, wherein
the contact surface is configured to space the baseplate apart from the cover such that baseplate sealing surfaces included in the baseplate and cover sealing surfaces included in the cover are spaced apart from one another by a gap.

Aspect 7. The reticle pod according to aspect 6, wherein the gap has a width in a range from 20 μm to 1 mm.

Aspect 8. The reticle pod according to any of aspects 6-7, further comprising an outer pod configured to accommodate the inner pod and the one or more spacers.

Aspect 9. The reticle pod according to any of aspects 6-8 wherein the depression is a gripper pocket formed in the baseplate, and the contact surface is configured to contact the cover.

Aspect 10. The reticle pod according to any of aspects 6-9, wherein the spacer further comprises a handling feature extending from the body.

Aspect 11. The reticle pod according to any of aspects 6-10, wherein the one or more spacers includes a plurality of the spacers.

Aspect 12. The reticle pod according to aspect 11, wherein at least two of the plurality of the spacers are joined to one another by at least one handling feature.

Aspect 13. The reticle pod according to any of aspects 6-12, wherein the spacers only contact the cover outside of the cover sealing surfaces and only contact the baseplate outside of the baseplate sealing surfaces.

Aspect 14. A method of preparing a reticle pod for shipment, comprising:
placing one or more spacers into depressions formed in one of a cover or a baseplate of a reticle pod; and
assembling the cover and the baseplate to form an inner pod of the reticle pod, wherein the spacers contact the cover and the baseplate;
wherein the cover and the baseplate are separated by a gap.

Aspect 15. The method according to aspect 14, wherein the gap has a width in a range from 20 μm to 1 mm.

Aspect 16. The method according to any of aspects 14-15, wherein the depression is a gripper pocket formed in the baseplate, and the contact surface is configured to contact the cover.

Aspect 17. The method according to any of aspects 14-16 wherein the cover includes one or more cover sealing surfaces, the baseplate includes one or more baseplate sealing surfaces, and the spacers only contact the cover outside of the cover sealing surfaces and only contact the baseplate outside of the baseplate sealing surfaces.

Aspect 18. The method according to any of aspects 14-17, further comprising placing the inner pod into an outer pod, the outer pod including a pod dome and a pod door; and joining the pod dome to the pod door to enclose the inner pod of the reticle pod within the outer pod.

Aspect 19. The method according to aspect 18, further comprising shipping the reticle pod from a packing location to a destination location while the pod dome is joined to the pod door.

Aspect 20. The method according to aspect 19, further comprising removing the spacers from the reticle pod at the destination location.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article comprising:
a spacer for a reticle pod, the spacer including:
a base of the spacer configured to engage with a depression formed in one of a cover or a baseplate of the reticle pod; and
a contact surface of the spacer configured to contact the other of the cover or the baseplate, wherein:
the contact surface is configured to space the cover apart from the baseplate such that sealing surfaces included in the cover and the baseplate are spaced apart from one another by a gap.

2. The article of claim 1, wherein the gap has a width in a range from 20 μm to 1 mm.

3. The article of claim 1, wherein the spacer comprises a thermoplastic

4. The article of claim 1, wherein the depression is a gripper pocket formed in the first inner pod segment.

5. The article of claim 1, wherein the spacer further comprises a handling feature extending from the body.

6. A reticle pod, comprising:
an inner pod including a baseplate and a cover; and
one or more spacers, each spacer including:
a base configured to engage with a depression formed in one of the baseplate or the cover; and
a contact surface configured to contact the other of the baseplate or the cover, wherein
the contact surface is configured to space the baseplate apart from the cover such that baseplate sealing surfaces included in the baseplate and cover sealing surfaces included in the cover are spaced apart from one another by a gap.

7. The reticle pod of claim 6, wherein the gap has a width in a range from 20 μm to 1 mm.

8. The reticle pod of claim 6, further comprising an outer pod configured to accommodate the inner pod and the one or more spacers.

9. The reticle pod of claim 6, wherein the depression is a gripper pocket formed in the baseplate, and the contact surface is configured to contact the cover.

10. The reticle pod of claim 6, wherein the spacer further comprises a handling feature extending from the body.

11. The reticle pod of claim 6, wherein the one or more spacers includes a plurality of the spacers.

12. The reticle pod of claim 11, wherein at least two of the plurality of the spacers are joined to one another by at least one handling feature.

13. The reticle pod of claim 6, wherein the spacers only contact the cover outside of the cover sealing surfaces and only contact the baseplate outside of the baseplate sealing surfaces.

14. A method of preparing a reticle pod for shipment, comprising:
placing one or more spacers into depressions formed in one of a cover or a baseplate of a reticle pod; and
assembling the cover and the baseplate to form an inner pod of the reticle pod, wherein the spacers contact the cover and the baseplate;
wherein the cover and the baseplate are separated by a gap.

15. The method of claim 14, wherein the gap has a width in a range from 20 μm to 1 mm.

16. The method of claim 14, wherein the depression is a gripper pocket formed in the baseplate, and the contact surface is configured to contact the cover.

17. The method of claim 14, wherein the cover includes one or more cover sealing surfaces, the baseplate includes one or more baseplate sealing surfaces, and the spacers only contact the cover outside of the cover sealing surfaces and only contact the baseplate outside of the baseplate sealing surfaces.

18. The method of claim 14, further comprising placing the inner pod into an outer pod, the outer pod including a pod dome and a pod door; and
joining the pod dome to the pod door to enclose the inner pod of the reticle pod within the outer pod.

19. The method of claim 18, further comprising shipping the reticle pod from a packing location to a destination location while the pod dome is joined to the pod door.

20. The method of claim 19, further comprising removing the spacers from the reticle pod at the destination location.
